(19) United States
(12) Patent Application Publication
(10) Pub. No.: US 2013/0075891 A1
(43) Pub. Date: Mar. 28, 2013

(54) FLIP CHIP TYPE FULL WAVE RECTIFICATION SEMICONDUCTOR DEVICE AND ITS MANUFACTURING METHOD

(71) Applicants: Wen-Ping HUANG, New Taipei City (TW); Paul Wu, New Taipei City (TW)

(72) Inventors: Wen-Ping HUANG, New Taipei City (TW); Paul Wu, New Taipei City (TW)

(73) Assignee: FORMOSA MICROSEMI CO., Ltd., New Taipei City (TW)

(21) Appl. No.: 13/241,545

(22) Filed: Sep. 23, 2011

(51) Int. Cl. H01L 23/498; H01L 21/50

(52) U.S. Cl. 257/737; 438/108; 257/778; 257/E21.499; 257/E23.068

(57) ABSTRACT

This invention reveals a flip-chip type full-wave rectification semiconductor device which includes at least a PNNP type and/or NPPN type flip-chip, and a sheet stuff or substrate including a plurality pins, and which is characterized in that: all the soldering points (bumps) of the PNNP type and/or the NPPN type flip-chip are on an identical surface, this can make easy connecting of the pins with the bumps of the flip-chips by soldering in pursuance of circuit arrangement of the full-wave rectification device, and complete manufacturing product after the steps of shaping/packing and cutting; such product has a function of making full-wave rectifying, and can simplify the manufacturing process, reduce the manufacturing cost, and get an effect of reducing the size of the product with better heat dissipation, being different from traditional full wave rectification semiconductor devices composed of two/four grains.

### BACKGROUND OF THE INVENTION

1. Field of the Invention

The present invention relates to a technique of semiconductor/electronic device, and especially to a flip-chip type full-wave rectification semiconductor device and a manufacturing method of this semiconductor device.

2. Description of the Prior Art

As well known, there are two kinds of full-wave rectifiers: bridge rectifiers and center-tap full-wave rectifiers, wherein the principle of operation of a bridge rectifier is to use four half-wave rectifier diodes, namely, it is composed of four diodes, for the purpose to carry out full-wave rectifying on an alternating power source, to convert the alternating power source to a direct power source for outputting; while a center-tap full-wave rectifier is applicable to an electric circuit assembly of which a transformer is of a center-tap type, using two diodes leaning against each other back to back (P electrode to P electrode or N electrode to N electrode) can make full-wave rectifying; these full-wave rectifiers are widely applied in the field of electronic technique, they are quite important electronic devices.

By virtue that: after necessary electrically connecting of eight electrodes of four diodes, and then the four pins of the four diodes are connected to an external circuit (two of the pins are electrically alternating current put out while the other two are direct current electrically put in), thereby the method of manufacturing and structure of the bridge rectifiers sold in the markets have four PN type individual grains placed on a supporting stand (conductor stand), the eight electrodes (soldering points) are respectively connected by the mode of jumper wiring, and then are shaped, packed and cut to expose the four pins for electric connecting with external circuits; such a manufacturing process of jumper wiring and shaping/packing is over-elaborate and complicated, its cost of manufacturing is higher, and its space larger.

Another kind of center-tap full-wave rectifiers each only composed of two PN type individual grains, and is electric connected with external circuits with three pins, however, its method of manufacturing is same as the above bridge rectifiers, it needs two PN type individual grains to be placed on a supporting stand for making a product through jumper wiring, shaping/packing and cutting, it has the similar defects of having over-elaborate and complicated manufacturing process and higher cost of manufacturing as those of the aforesaid bridge rectifiers.

Moreover, another manufacturing method/structure of a bridge rectifier has four PN type grains arranged to make the electrodes (soldering points) of the grains be allocated on and beneath the electrodes respectively, and then an upper and a lower sheet stuff (like the above mentioned supporting stand or conductor stand) are connected respectively with the electrodes of the PN type grains in the manufacturing process, and then the processes of shaping/packing and cutting are taken. Such a manufacturing method/structure can get rid of the process of jumper wiring, but the structure must have at least an upper and a lower sheet stuff for connecting with four PN type grains, as compared with the above mentioned conventional mode of jumper wiring, this another manufacturing method/structure of bridge rectifier does not give any evident effect of gain no matter in regard to the manufacturing process, the device size or the manufacturing cost.

In view of these, the inventor of the present invention provided a flip-chip type full-wave rectification semiconductor device based on his practical experience in the field of semiconductor/silicon grains for years, which device has gotten rid of the problems resided in the conventional techniques in manufacturing.

### SUMMARY OF THE INVENTION

The object of the present invention is to provide a flip-chip type full-wave rectification semiconductor device made by using individual sheet stuffs or substrates; the device not only can simplify manufacturing process, reduce the manufacturing cost, and get an effect of reducing the device size.

In order to achieve the above stated object, the method of manufacturing a flip-chip type full-wave rectification semiconductor device the of the present invention at least uses a PNNP type and/or NPPN type flip-chip, and a sheet stuff or substrate including a plurality pins, wherein: all the soldering points (bumps) of the PNNP type and/or NPPN type flip-chip are on an identical surface, this can make easy connecting of the pins of the sheet stuff or substrate with the bumps of the flip-chip by soldering in pursuance of circuit arrangement of the full-wave rectification device, and complete product manufacturing after the steps of shaping/packing and cutting.

Another object of the present invention is to provide a flip-chip type full-wave rectification semiconductor device which includes:

a PNNP type and an NPPN type flip-chip separated from each other, all the bumps of them are located on an identical surface;

four pins each having at least a connecting end and a circuit connecting end, wherein the connecting ends of the four pins are respectively connected by soldering with the bumps of the aforesaid two flip-chips according to the circuit arrangement of a bridge rectifier, the four circuit connecting ends can be electrically connected with an external circuit; and

a packing member enveloping the outer portions of the above two flip-chips and the four pins, and making exposing of the circuit connecting ends of the four pins.

Another embodiment of the flip-chip type full-wave rectification semiconductor device of the present invention includes:

a PNNP type or an NPPN type flip-chip, all the bumps of them are located on an identical surface;

three pins each having at least a connecting end and a circuit connecting end, wherein the connecting ends of the three pins are respectively connected by soldering with the bumps of a flip-chip according to the circuit arrangement of a center-tap full-wave rectifier, the three circuit connecting ends can be electrically connected with an external circuit; and

a packing member enveloping the outer portions of the above flip-chip and the three pins, and making exposing of the circuit connecting ends of the three pins.

By virtue that all the bumps of the PNNP type and the NPPN type flip-chips are located on an identical surface, in the process of manufacturing, all the pins can be connected by soldering with the bumps after being extended from an identical sheet stuff or substrate, this not only makes a simplified process, but also can save cost of producing, and the size of the device can be reduced.

And particularly, if all the bumps of the of the PNNP type and the NPPN type flip-chips are located on an identical surface, the process of alignment of the flip-chips with the pins can be more accurate and convenient, thus rate of superiority such as heat dissipation/size etc. of the products can be increased.

In practicing, the circuit connecting ends of the pins can be made to meet the style of a surface mounting type device (SMD) or a conventional dual in-line package type device (DIP).

For the convenience of soldering, the bumps of the PNNP type/the NPPN type flip-chips can be provided in antecedence with soldering material for connecting of the connecting ends with the bumps.

In practicing, two neighboring N electrodes of the PNNP type flip-chip can be co-constructed with each other, thereby the amount of the bumps of the flip-chips with the pins can be reduced, this can further simplify the process of the soldering step; similarly, two neighboring P electrodes of the NPPN type flip-chip also can be co-constructed with each other to achieve the object of the above stated process of simplifying.

Moreover, the P electrodes of the PNNP and/or the NPPN type flip-chips can be made as required by an ordinary semiconductor silicon chip manufacturing technique or a Schottky manufacturing technique, in order that the P electrodes of the PNNP type flip-chip and/or the NPPN type flip-chip can have the electrical characteristic of a normal semiconductor or a Schottky Barrier device.

As to how the PNNP and/or the NPPN type flip-chips are made and how the bumps of the PNNP type and the NPPN type flip-chips are located on an identical surface, we can take reference to the patent applications with serial numbers of: TW 099106657, CN 201048162.1 and U.S. Ser. No. 12/662,792; and no further narration is required here.

As compared with the prior art, the flip-chip type full-wave rectification semiconductor device of the present invention and its manufacturing method can simplify the process of manufacturing, in order to attained the object of reducing working hours and cost, and largely reducing the size of products, thus it has a substantially high industrial value in use.

The present invention will be apparent in its technical measures after reading the detailed description of the preferred embodiment thereof in reference to the accompanying drawings.

### BRIEF DESCRIPTION OF THE DRAWINGS

FIG. 1 is a schematic view showing connecting of a PNNP and an NPPN type flip-chip with a sheet stuff of the present invention;

FIG. 2 is another schematic view showing connecting of a PNNP or an NPPN type flip-chip with a sheet stuff of the present invention;

FIG. 3 is a schematic view showing circuit arrangement of the present invention together with a bridge rectifier;

FIG. 4 is a schematic view showing circuit arrangement of the present invention together with a center-tap full-wave rectifier;

FIG. 5 is a schematic view showing four pins are provided on a sheet stuff, wherein each set of pins are connected with two flip-chips by soldering in the present invention;

FIG. 6 is a schematic view showing four pins are provided on a substrate, wherein each set of pins are connected with two flip-chips by soldering in the present invention;

FIG. 7 is another schematic view showing four pins are provided on a sheet stuff, wherein each set of pins are too connected with two flip-chips by soldering in the present invention;

FIG. 8 is a schematic view showing three pins are provided on a sheet stuff, wherein each set of pins are connected with one flip-chip by soldering in the present invention;

FIG. 9 is a perspective schematic view showing the appearance of a product of surface mounting type device which is made after the processes of shaping/packing and cutting of the present invention as of FIG. 5;

FIG. 10 is a perspective schematic view showing the appearance of a product of dual in-line package type device which is made after the processes of shaping/packing and cutting of the present invention as of FIG. 7;

FIG. 11 is a perspective schematic view showing the appearance of a product of surface mounting type device which is made after the processes of shaping/packing and cutting of the present invention as of FIG. 8.

### DETAILED DESCRIPTION OF THE PREFERRED EMBODIMENT

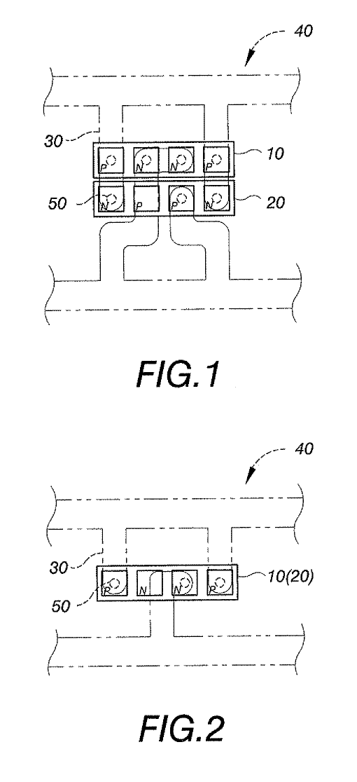

As shown in FIGS. 1 and 2, in the manufacturing method, the flip-chip type full-wave rectification semiconductor device of the present invention at least is comprised of a PNNP type flip-chip 10 and/or an NPPN type flip-chip 20, and a sheet stuff or substrate 40 including a plurality pins 30, wherein: all the soldering points (bumps) 50 of the PNNP type flip-chip 10 and/or the NPPN type flip-chip 20 are on an identical surface, this can make easy connecting of the pins 30 of the sheet stuff or substrate 40 with the bumps 50 of the flip-chip 10 (20) by soldering in pursuance of circuit arrangement of the full-wave rectification device, and complete manufacturing product after the steps of shaping/packing and cutting.

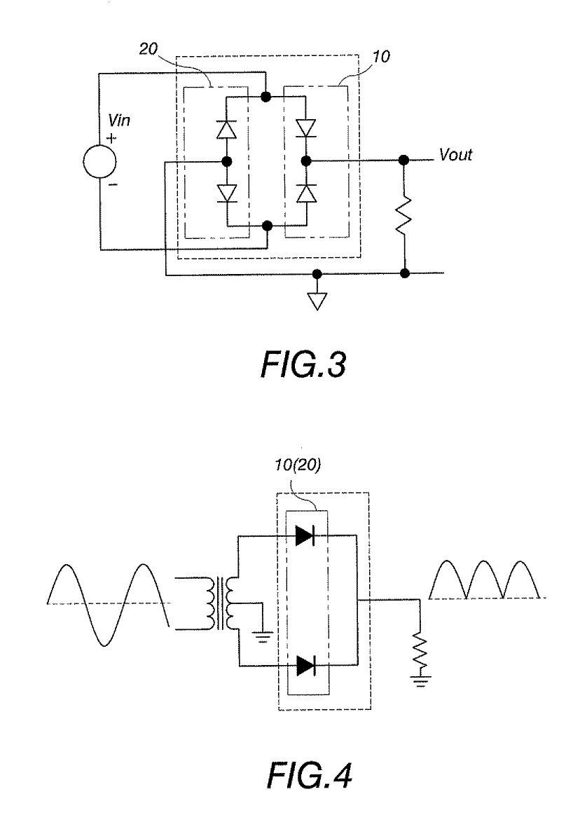

The above stated circuit arrangement of the flip-chip type full-wave rectification device is shown as in FIGS. 3 and 4, wherein FIG. 3 generally is called a circuit diagram of a bridge rectifier; in using in the practicing of the present invention, the flip-chip of it can be a composition of two grains, i.e., a PNNP type flip-chip 10 and an NPPN type flip-chip 20; FIG. 4 is a circuit diagram of a center-tap full-wave rectifier; in using in the practicing of the present invention, the flip-chip of it can be singly a PNNP type flip-chip 10 or an NPPN type flip-chip 20, and three pins 30 are used to connect them by soldering (FIG. 2).

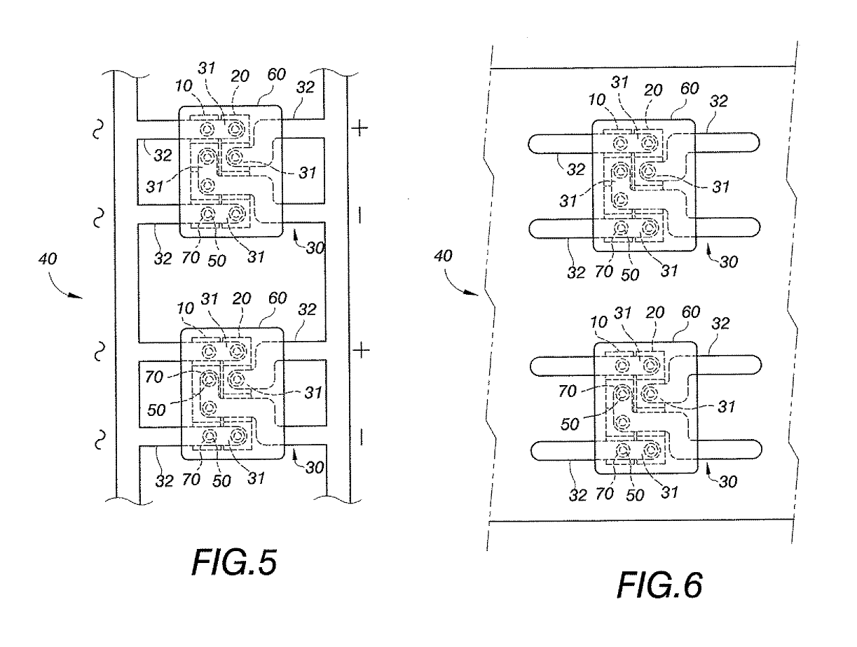

As shown in FIGS. 5 and 6, by virtue that all the soldering points (bumps) 50 of the PNNP type flip-chip 10 and the NPPN type flip-chip 20 are located on an identical surface, thereby in the processes of manufacturing, the pins 30 can be extended on the same sheet stuff or substrate 40, and are connected respectively with the bumps 50 by soldering. This not only can simplify the manufacturing process, reduce the manufacturing cost, and get an effect of reducing the size of the product with better heat dissipation. In FIG. 5, taking the sheet stuff as the representative of the sheet stuff and/or substrate 40; in FIG. 6, the substrate is the representative of the sheet stuff and/or substrate 40, the substrate can be a circuit board or a ceramic board, while the pins 30 are allocated to be the electric lines on the circuit board or ceramic board.

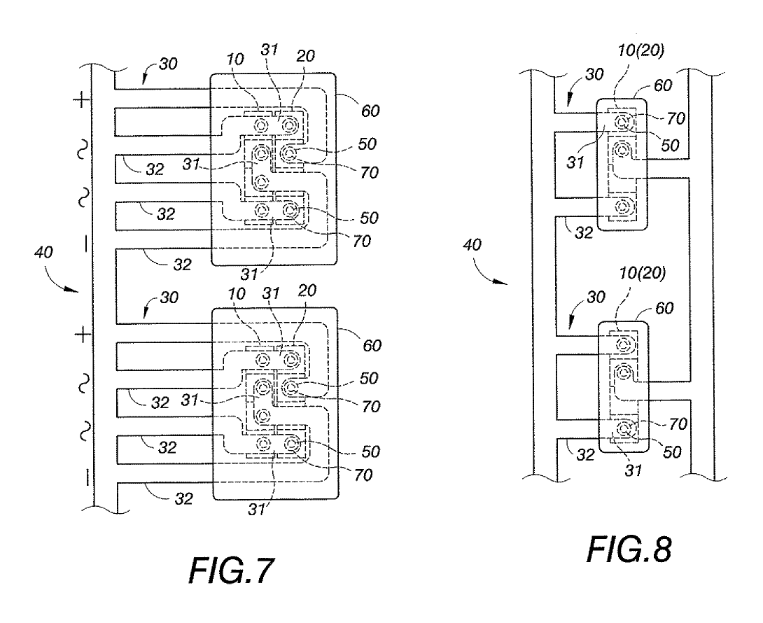

Particularly as shown in FIGS. 5-7, if the PNNP type flip-chip 10 and the NPPN type flip-chip 20 are evenly aligned, all the bumps 50 are aligned on an identical horizontal plane, thereby the process of alignment for the two flip-chips 10, 20 and the four pins 30 of the sheet stuff and/or substrate 40 can be more precise and more convenient to increase the superiority of products; likewise, as shown in FIG. 8, all the bumps 50 of a single PNNP type flip-chip 10 or NPPN type flip-chip 20 are aligned on an identical horizontal plane, this similarly can make more precise alignment in the processes of manufacturing.

Moreover, as shown in FIGS. 5-8, in the above processes of manufacturing, multiple sets of pins 30 can be provided on the same sheet stuff or substrate 40, each set of pins 30 can be connected by soldering in pursuance of circuit arrangement of the full-wave rectification device, and are shaped and packed with a packing member 60, then have their feet cut, thus mass production can be performed to reduced cost.

As shown in FIGS. 5-7, the flip-chip type full-wave rectification semiconductor device made according to the above manufacturing mode includes in its structure:

a PNNP type flip-chip 10 and an NPPN type flip-chip 20 separated from each other, all the bumps 50 of them are located on an identical surface;

four pins 30 each having at least a connecting end 31 and a circuit connecting end 32, wherein the connecting ends 31 of the four pins 30 are respectively connected by soldering with the bumps 50 of the aforesaid two flip-chips 10, 20 according to the circuit arrangement of a bridge rectifier, the four circuit connecting ends 32 can be electrically connected with an external circuit; and

a packing member 60 enveloping the outer portions of the above two flip-chips 10, 20 and the four pins 30, and making exposing of the circuit connecting ends 32 of the four pins 30.

By virtue that all the bumps 50 of the PNNP type and the NPPN type flip-chips 10, 20 on the product flip-chip type full-wave rectification semiconductor device of the present invention are located on an identical surface, in the process of manufacturing, all the four pins 30 can be respectively connected by soldering with the bumps 50 after being extended from an identical sheet stuff or substrate 40, this not only makes a simplified process, but also can save cost of producing, and the size of the device can be reduced. And particularly, if all the bumps 50 of the of the PNNP type and the NPPN type flip-chips 10, 20 are located on an identical horizontal surface, the process of alignment of the two flip-chips 10, 20 with the four pins 30 can be more accurate and convenient, thus rate of superiority such as heat dissipation/size etc. of the products can be increased.

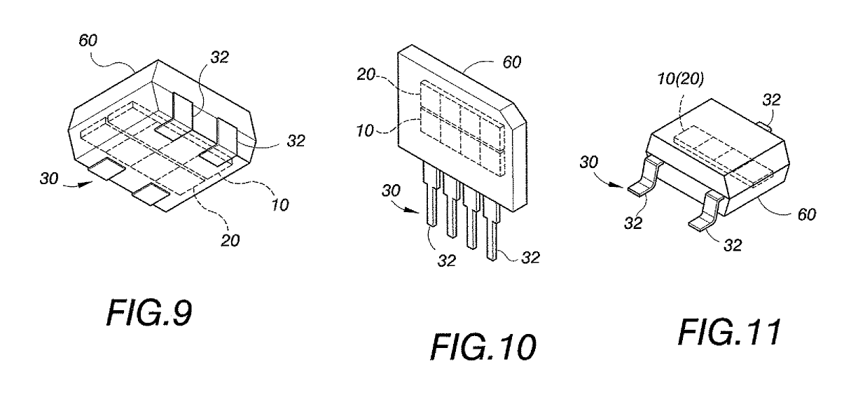

In practicing, the circuit connecting ends 32 of the four pins 30 are extended outwards from the packing member 60 to make the style of a surface mounting type device (SMD) as shown in FIG. 9 or a conventional dual in-line package type device (DIP) as shown in FIG. 10.

As shown in FIGS. 8/11, an embodiment of another flip-chip type center-tap full-wave rectification semiconductor device made according to the above manufacturing mode includes in its structure:

a PNNP type flip-chip 10 and/or an NPPN type flip-chip 20, all the bumps 50 of them are located on an identical surface;

three pins 30 each having at least a connecting end 31 and a circuit connecting end 32, wherein the connecting ends 31 of the three pins 30 are respectively connected by soldering with the bumps 50 of a flip-chip 10 (20) according to the circuit arrangement of a center-tap full-wave rectifier, three circuit connecting ends 32 thereof can be electrically connected with an external circuit; and

a packing member 60 enveloping the outer portions of the above flip-chip 10 (20) and the three pins 30, and making exposing of the circuit connecting ends 32 of the three pins 30.

Other examples: such as, all the bumps 50 of a flip-chip 10 (20) are located on an identical surface, and the mode of practicing for making the style of a surface mounting type device (SMD) or a dual in-line package type device (DIP) is taken, and the effect of gain in the process of manufacturing is same as that of the above disclosed embodiment, so no further narration is required here.

One thing is worth mentioning, please refer to FIGS. 5-8 again, for the convenience of soldering, in practicing, the above mentioned bumps 50 of the PNNP type flip-chip 10 and/or the NPPN type flip-chip 20 can be provided in antecedence at a position to be soldered to the connecting ends 31 of the pins 30 with soldering material 70, so that the connecting ends 31 can be conveniently connected with the bumps 50.

Further in practicing, two neighboring N electrodes of the PNNP type flip-chip 10 can be co-constructed with each other, thereby the amount of the bumps 50 of the flip-chips 10 (20) with the pins 30 can be reduced, this can further simplify the process of the soldering step; similarly, two neighboring N electrodes of the NPPN type flip-chip 20 also can be co-constructed with each other to achieve the object of the above stated process of simplifying. Moreover, the P electrodes of the PNNP type flip-chip 10 and/or the NPPN type flip-chip 20 can be made as required by an ordinary semiconductor silicon chip manufacturing technique or a Schottky/semiconductor manufacturing technique, in order that the P electrodes of the PNNP type flip-chip 10 and/or the NPPN type flip-chip 20 can have the electrical characteristic of a normal semiconductor or a Schottky Barrier device.

The names of the members stated above are only for the convenience of describing the technical content of the present invention, and not for giving any limitation to the scope of the present invention. It will be apparent to those skilled in this art that various equivalent modifications or changes without departing from the spirit of this invention can be made to the elements of the present invention and also fall within the scope of the appended claims.

1. A method of manufacturing a flip-chip type full-wave rectification semiconductor device, said method at least uses a PNNP type and/or an NPPN type flip-chip, and a sheet stuff or substrate including a plurality pins, wherein: all soldering points (bumps) of said PNNP type and/or NPPN type flip-chip are on an identical surface, when connecting of said pins of said sheet stuff or substrate with said bumps of said flip-chip(s) by soldering in pursuance of circuit arrangement of said full-wave rectification device, product manufacturing is completed after the steps of shaping/packing and cutting.

2. The method of manufacturing a flip-chip type full-wave rectification semiconductor device as in claim 1, wherein all soldering points (bumps) of said PNNP type flip-chip and/or said NPPN type flip-chip are aligned on an identical horizontal plane.

3. The method of manufacturing a flip-chip type full-wave rectification semiconductor device as in claim 1, wherein said circuit connecting ends of said pins are extended outwards from a packing member to make a surface mounting type device (SMD) or a dual in-line package type device (DIP).

4. The method of manufacturing a flip-chip type full-wave rectification semiconductor device as in claim 1, wherein two neighboring N electrodes of said PNNP type flip-chip are co-constructed with each other.

5. The method of manufacturing a flip-chip type full-wave rectification semiconductor device as in claim 1, wherein two neighboring P electrodes of said NPPN type flip-chip are co-constructed with each other.

6. The method of manufacturing a flip-chip type full-wave rectification semiconductor device as in claim 1, wherein said bumps of said PNNP type/NPPN type flip-chips are provided with soldering material for connecting of the connecting ends with said bumps.

7. The method of manufacturing a flip-chip type full-wave rectification semiconductor device as in claim 1, wherein P electrodes of said PNNP and/or said NPPN type flip-chip are made by an ordinary semiconductor silicon chip manufacturing technique or a Schottky/semiconductor manufacturing technique.

8. A flip-chip type full-wave rectification semiconductor device which includes:
a PNNP type and an NPPN type flip-chip separated from each other, all bumps of said flip-chip are located on an identical surface;
four pins each having at least a connecting end and a circuit connecting end, wherein said connecting ends of said four pins are respectively connected by soldering with said bumps of said two flip-chips according to circuit arrangement of a bridge rectifier, said four circuit connecting ends are electrically connected with an external circuit; and
a packing member enveloping outer portions of said two flip-chips and said four pins, and making exposing of said circuit connecting ends of said four pins.

9. The flip-chip type full-wave rectification semiconductor device as in claim 8, wherein all soldering points (bumps) of said two flip-chips are aligned on an identical horizontal plane.

10. The flip-chip type full-wave rectification semiconductor device as in claim 8, wherein said circuit connecting ends of said four pins are extended outwards from a packing member to make a surface mounting type device (SMD) or a dual in-line package type device (DIP).

11. The flip-chip type full-wave rectification semiconductor device as in claim 8, wherein two neighboring N electrodes of said PNNP type flip-chip are co-constructed with each other.

12. The flip-chip type full-wave rectification semiconductor device as in claim 8, wherein two neighboring P electrodes of said NPPN type flip-chip are co-constructed with each other.

13. The flip-chip type full-wave rectification semiconductor device as in claim 8, wherein said P electrodes of said PNNP type flip-chip and said NPPN type flip-chip have an electrical characteristic of a normal semiconductor or a Schottky Barrier device.

14. A flip-chip type full-wave rectification semiconductor device which includes:
a PNNP type or an NPPN type flip-chip, all bumps of said flip-chip are located on an identical surface;
three pins each having at least a connecting end and a circuit connecting end, wherein said connecting ends of said three pins are respectively connected by soldering with said bumps of said two flip-chip according to circuit arrangement of a center-tap full-wave rectifier, said three circuit connecting ends are electrically connected with an external circuit; and
a packing member enveloping outer portions of said flip-chip and said three pins, and making exposing of said circuit connecting ends of said three pins.

15. The flip-chip type full-wave rectification semiconductor device as in claim 14, wherein all soldering points (bumps) of said two flip-chips are aligned on an identical horizontal plane.

16. The flip-chip type full-wave rectification semiconductor device as in claim 14, wherein said circuit connecting ends of said three pins are extended outwards from a packing member to make a surface mounting type device (SMD) or a dual in-line package type device (DIP).

17. The flip-chip type full-wave rectification semiconductor device as in claim 14, wherein two neighboring N electrodes of said PNNP type flip-chip are co-constructed with each other.

18. The flip-chip type full-wave rectification semiconductor device as in claim 14, wherein two neighboring P electrodes of said NPPN type flip-chip are co-constructed with each other.

19. The flip-chip type full-wave rectification semiconductor device as in claim 14, wherein said P electrodes of said PNNP type flip-chip or said NPPN type flip-chip have an electrical characteristic of a normal semiconductor or a Schottky Barrier device.
